(19) United States
(12) Patent Application Publication
(10) Pub. No.: US 2026/0110108 A1
(43) Pub. Date: Apr. 23, 2026

(54) INGOT GROWTH APPARATUS

(71) Applicants: Ji Wook SEO, Seoul (KR); Yang Kyu KIM, Seoul (KR)

(72) Inventors: Ji Wook SEO, Seoul (KR); Yang Kyu KIM, Seoul (KR)

(21) Appl. No.: 19/474,399

(22) PCT Filed: Mar. 14, 2024
(86) PCT No.: PCT/KR2024/095525

§ 371 Date: Nov. 7, 2025

(51) Int. Cl. C30B 15/12; C30B 15/00; C30B 29/06

(52) U.S. Cl. CPC C30B 15/12; C30B 15/002; C30B 29/06

(57) ABSTRACT

An ingot growth apparatus may include an ingot growth furnace which heats molten silicon and an auxiliary melting furnace which melts solid silicon and supplies the molten silicon to the ingot growth furnace, wherein the auxiliary melting furnace may include an auxiliary crucible which melts the solid silicon, a first transfer path connected to the auxiliary crucible and connected to the ingot growth furnace, and a partition wall which extends downward from an upper surface of the auxiliary crucible, is located between a center of the auxiliary crucible and an inlet of the first transfer path, and extends between two facing points of an inner surface of the auxiliary crucible.

### TECHNICAL FIELD

The present disclosure relates to an ingot growth apparatus.

### BACKGROUND ART

The Czochralski crystal growth method is one method of manufacturing single crystal silicon wafers which are raw materials of semiconductors, and in the Czochralski crystal growth method, silicon is input to a crucible, heated, and melted. In addition, a single crystal seed is brought into contact with the molten silicon and moved upward while being rotated in one direction to grow an ingot with a predetermined diameter. Within the Czochralski crystal growth method, a method of growing an ingot by continuously injecting a silicon material into a crucible is called a continuous growth type Czochralski method.

In the conventional continuous growth type Czochralski method, solid silicon (polysilicon) is input as a silicon material, and there are problems that it takes time to melt the solid silicon, and an ingot or crucible is contaminated by particles included in the solid silicon.

The above-described background art is technical information that the inventor had when deriving the present invention or obtained while deriving the present invention and is not necessarily known technology that was disclosed to the general public prior to the application of the present invention.

### DETAILED DESCRIPTION OF INVENTION

### Technical Problem

The present disclosure is directed to providing an ingot growth apparatus in which an ingot growth furnace, an auxiliary melting furnace, and a silicon feeder are modularized and the ingot growth furnace is prevented from being contaminated by foreign matter contained in solid silicon.

However, the objects are only exemplary, and objects to be solved by the present disclosure are not limited thereto.

### Technical Solution

One aspect of the present invention provides an ingot growth apparatus including an ingot growth furnace which heats molten silicon and an auxiliary melting furnace which melts solid silicon and supplies the molten silicon to the ingot growth furnace, wherein the auxiliary melting furnace includes an auxiliary crucible which melts the solid silicon, a first transfer path connected to the auxiliary crucible and connected to the ingot growth furnace, and a partition wall which extends downward from an upper surface of the auxiliary crucible, is located between a center of the auxiliary crucible and an inlet of the first transfer path, and extends between two facing points of an inner surface of the auxiliary crucible.

A lower end of the partition wall may be located at a higher level than a lower end of the inlet of the first transfer path, and a distance between the partition wall and the inlet of the first transfer path may be smaller than a distance between the partition wall and a center of the auxiliary crucible.

The partition wall may include a groove formed by cutting a portion of a lower end portion of the partition wall, and a height of a portion of the partition wall close to the inner surface of the auxiliary crucible may be greater than a height of a central portion of the partition wall.

Gaps may be formed between both ends of the partition wall in a longitudinal direction and the inner surface of the auxiliary crucible.

The partition wall may include a main body portion extending downward from the upper surface of the auxiliary crucible and an inclined portion which extends to be inclined from the main body portion toward the first transfer path and is spaced apart from the inlet of the first transfer path.

The auxiliary melting furnace may include a first hopper which transfers the solid silicon from a silicon feeder to the auxiliary crucible and may be connected to the auxiliary crucible through an input port, and a central axis of the first hopper may be located at a side opposite to the partition wall based on a central axis of the auxiliary crucible.

The first hopper may include a support rod located on the central axis of the first hopper, a raw material input path through which the first hopper and the silicon feeder are connected, and a guide including a pair of inclined surfaces which are located on a lower end of the support rod to be located under the raw material input path and are inclined downward toward an inner surface of the first hopper.

A distance between the central axis of the first hopper and the central axis of the auxiliary crucible may range from 30% to 70% of a radius of the auxiliary crucible, a distance between the partition wall and the inlet of the first transfer path may range from 20% to 70% of a distance between the partition wall and the center of the auxiliary crucible, and a length of the partition wall may range from 1.1 to 1.5 times the radius of the auxiliary crucible.

Other aspects, features, advantages in addition to the above-described contents will be clear from specific contents, claims, and drawings for implementing the invention below.

### Advantageous Effects

In an ingot growth apparatus according to some embodiments of the present disclosure, since an auxiliary melting furnace includes a partition wall, foreign matter contained in an unmolten solid silicon or solid silicon can be prevented from being introduced into an ingot growth furnace.

Two or more of an ingot growth furnace, an auxiliary melting furnace, and a silicon feeder included in an ingot growth apparatus according to some embodiments of the present disclosure can be freely separated and dissembled form each other.

### DESCRIPTION OF DRAWINGS

FIG. 1 shows an entire ingot growth apparatus.

FIGS. 2 to 4 show portions of the ingot growth apparatus.

FIG. 5 shows an inner portion of the ingot growth furnace.

FIG. 6 shows an inner portion of an auxiliary melting furnace.

FIG. 7 shows the enlarged inner portion of the auxiliary melting furnace of FIG. 6.

FIG. 8 shows an inner portion of a silicon feeder.

FIG. 9 shows the auxiliary melting furnace.

FIG. 10 shows partition walls according to some embodiments.

FIG. 11 shows an auxiliary melting furnace according to another embodiment.

### BEST MODE OF THE INVENTION

An ingot growth apparatus may include an ingot growth furnace which heats molten silicon and an auxiliary melting furnace which melts solid silicon and supplies the molten silicon to the ingot growth furnace, wherein the auxiliary melting furnace may include an auxiliary crucible which melts the solid silicon, a first transfer path connected to the auxiliary crucible and connected to the ingot growth furnace, and a partition wall which extends downward from an upper surface of the auxiliary crucible, is located between a center of the auxiliary crucible and an inlet of the first transfer path, and extends between two facing points of an inner surface of the auxiliary crucible.

### Modes of the Invention

Embodiments of the present disclosure may be understood with reference to the descriptions and accompanying drawings of the invention. The embodiments which will be described may have various modified embodiments and be implemented in various different forms and are not limited to the embodiments described in the present specification. In addition, features of the various embodiments of the present disclosure may be partially or entirely combined. The embodiments may be implemented independently of or in relation to each other. The described embodiments are provided as examples such that the present disclosure is complete and is to completely transfer the spirit of the present disclosure to those skilled in the art to which the present disclosure belongs. The present disclosure may be substituted by modifications and equivalents within the spirit and technical ranges of the present invention. Accordingly, processes, elements, and technologies that are not necessary for those skilled in the art for complete understanding of the embodiments of present disclosure may not be described.

Unless otherwise additionally illustrated in the accompanying drawings and described elsewhere in the specification, since the same reference symbols, letters, or combinations thereof indicate the same components, redundant descriptions thereof will be omitted. In addition, portions unrelated to descriptions will be omitted to clearly describe the present invention.

In the drawings, relative sizes of elements, layers, and regions may be exaggerated for clarity. In the accompanying drawings, hatching and/or shading is generally used to clarify a boundary between adjacent elements. Accordingly, the presence of the hatching or shading does not indicate a specific material, a material feature, a dimension, a ratio, a commonality between drawn elements and/or other features, properties, and exemplary forms or requirements for the properties of an element unless otherwise indicated.

Various embodiments will be described in the present specification with reference to examples and/or exemplary cross sections which are schematic examples of intermediate structures. Accordingly, for example, a shape in a drawing may be changed as a result of a manufacturing technology and/or a tolerance. In addition, a specific structural or functional description described in the present specification is merely exemplary for describing an embodiment according to a concept of the present invention. Accordingly, the embodiments disclosed in the present specification should not be interpreted as being limited to shapes of illustrated regions, and, for example, include deviations of forms according to manufacturing.

A region illustrated in a drawing is essentially a schematic region, and a shape of the region is not for illustrating an actual shape of the region of an apparatus and is not intended to limit the shape. In addition, as will be recognized by those skilled in the art, embodiments which will be described may be modified in various manners within a region not departing from the spirit and scope of the present disclosure.

In the specification, several specific details are suggested to provide complete understanding of various embodiments. However, the various embodiments may be made without the specific details or with one or more of the specific details. In another case, well-known structures and apparatuses will be illustrated in forms of block diagrams in order to avoid unnecessarily obscuring the various embodiments.

As illustrated in the drawings, spatially relative terms, such as “below,” “above,” “lower,” and “upper,” may be used here in order to easily describe relationships between features of one element and features of another element. The spatially relative terms are intended to include various directions of used or operated apparatuses in addition to directions illustrated in the drawings. For example, when an apparatus in a drawing is turned upside down, one element having a feature described as being “below” or “under” another element may then be located above the other element. Accordingly, the illustrative terms, such as “below” and “under,” may indicate both upward and downward directions. An apparatus may face in different directions (for example, turned 90° or facing in another direction), and a spatially relative description used in the present specification should be interpreted accordingly. Similarly, when a first portion is described as being disposed above a second portion, it means that the first portion is disposed above or below the second portion.

In addition, descriptions such as “viewed on a plane” means that an object is viewed from above, and descriptions such as “in a schematic cross-sectional view” mean that an object is vertically cut and a schematic cross section thereof is viewed. Descriptions such as “laterally viewed” mean that a first object may be disposed above, below, or beside a second object and the inverse case is also possible. In addition, terms such as “overlapping” or “superposition” may include layering, stacking, facing, extending, covering, partially covering, or any other suitable term understood by those skilled in the art. Terms such as “not overlapping” may include a meaning of “separated from” or “spaced apart from” and any other equivalent suitable term recognized and understood by those skilled in the art. Terms such as “side” and “surface” may mean that a first object may directly or indirectly face a second object. When a third object is located between a first object and a second object, it may be understood that the first object and the second object face each other or indirectly face each other.

When an element, layer, region, or component is described as being “formed on,” “connected to,” or “coupled to” another element, layer, region, or component, the element, layer, region, or component may be directly formed thereon, formed on another element, layer, region, or component, or indirectly formed on, connected to, or coupled to the other element, layer, region, or component. In addition, descriptions such as “formed on,” “connected to,” or “coupled to” may generally mean direct or indirect coupling or connection or integral or nonintegral coupling or connection between elements, layers, regions, or components with one or more other elements, layers, regions, or components present. For example, when an element, layer, region, or component is described as being “electrically connected” or “electrically coupled” to another element, layer, region, or component, the element, layer, region, or component may be directly electrically connected or coupled the other element, layer, region, or component, or still another element, layer, region, or component may be present therebetween. However, descriptions such as “direct connection” or “direction coupling” mean that one component is directly connected to, coupled to, or located on another component with no other component therebetween. In addition, in the present specification, in a case in which a portion of a layer, a film, a region, a guide plate, or the like is formed on another portion, a forming direction thereof is not limited to an upward direction and the portion may be formed on a side surface or a lower portion of the other portion. Conversely, cases in which a portion of a layer, film, region, guide plate, or the like is formed “under” another portion includes not only a case in which the portion is disposed directly under the other portion but also a case in which still another portion is located between the portion and the other portion. Meanwhile, other descriptions for describing relationships between components, such as “between,” “exactly between,” “adjacent to,” and “directly adjacent to” may be similarly interpreted. In addition, when an element or layer is described as being located “between” two elements or layers, the element may be only one element located between the two elements or layers, or there may be another element therebetween.

For an object of the present specification, descriptions such as “at least one or more” or “any one” do not limit an order of individual elements. For example, “at least one of X, Y, and Z,” “at least one of X, Y, or Z,” or “at least one selected from the group consisting of X, Y, and Z” may include a single X, a single Y, a single Z, or any combination of two or more of X, Y and Z. Similarly, descriptions such as “at least one of A and B” and “at least one of A or B,” may include A, B, or A and B. In the present specification, terms such as “and/or” includes any combination of one or more related items. For example, the description “A and/or B,” may include A, B, or A and B.

Terms such as “first,” “second,” and “third” may be used in the present specification to describe various elements, components, regions, layers, and/or cross sections, but the elements, components, regions, layers, and/or cross sections are not limited by such terms. Such terms are used to distinguish an element, component, region, layer, or cross section from another element, component, region, layer, or cross section. Accordingly, a first element, component, region, layer, or cross section which will be described below may be termed a second element, component, region, layer, or cross section without departing from the spirit and scope of the present invention. The description of an element as a “first element” may not require or imply a second element or another element. Terms such as “first” or “second” may also be used in the present specification to distinguish different categories or element sets. For clear description, terms such as “first” or “second” may indicate a “first category (or first set),” “second category (or second set),” or the like.

The terminology used herein is for the purpose of describing specific embodiments only and is not intended to limit the present invention. As described in the present specification, the singular forms are intended to include the plural forms, and unless the context clearly indicates otherwise, the plural forms are intended to include the singular forms. In the present specification, terms such as “comprise,” “include,” and “have” used in the present specification are meant to specify the presence of stated features, numbers, and steps thereof. The terms do not preclude the presence or addition of one or more other functions, steps, operations, components, and/or groups thereof.

When one or more embodiments may be implemented in different manners, a specific process may be performed according to an order different from a described order. For example, two processes that are sequentially described may be actually simultaneously performed or performed in an order opposite to a described order.

Terms such as “actually,” “about,” “substantially,” and similar terms are used as terms of approximation, and mean that a range of an intrinsic deviation (for example, a deviation range due to the limitation of a measurement system) of a measured or calculated value is satisfied. For example, terms such as “about” may mean within a standard deviation of one or more values or a range within ±30%, 20%, 10%, or 5% of a stated value.

Unless otherwise defined, all terms including technical and scientific terms used herein have meanings which are the same as meanings generally understood by those skilled in the art. Terms such as those defined in commonly used dictionaries should be interpreted as having meanings that are consistent with their meanings in the context of the relevant art and will not be interpreted in an idealized or overly formal sense unless explicitly defined here.

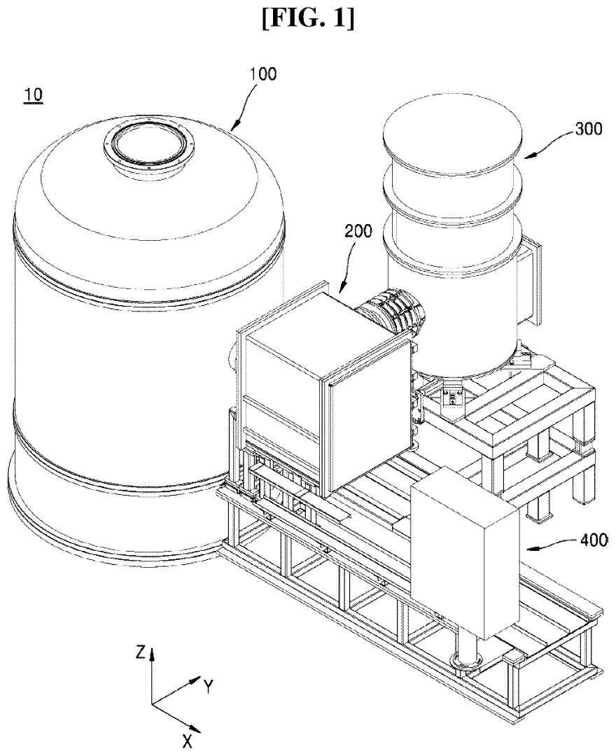

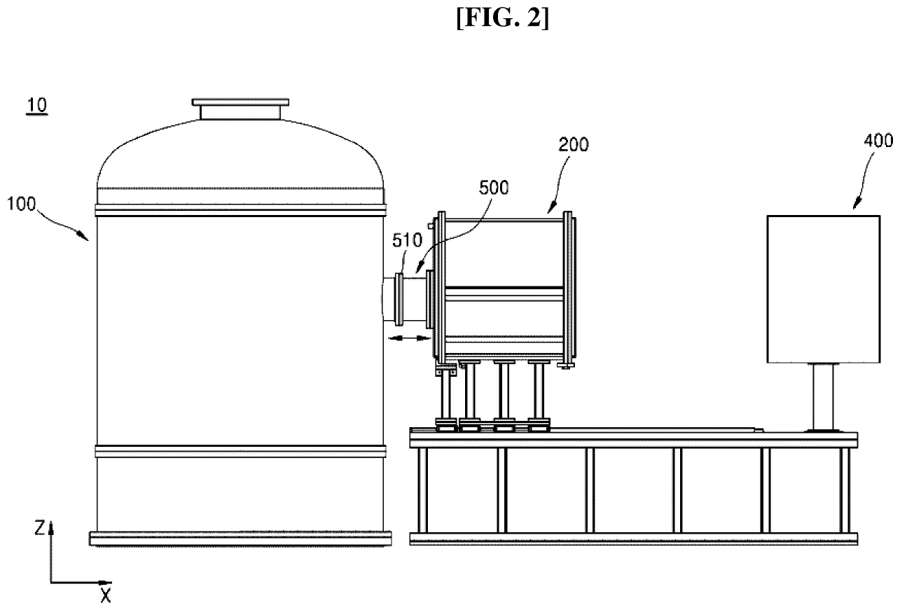

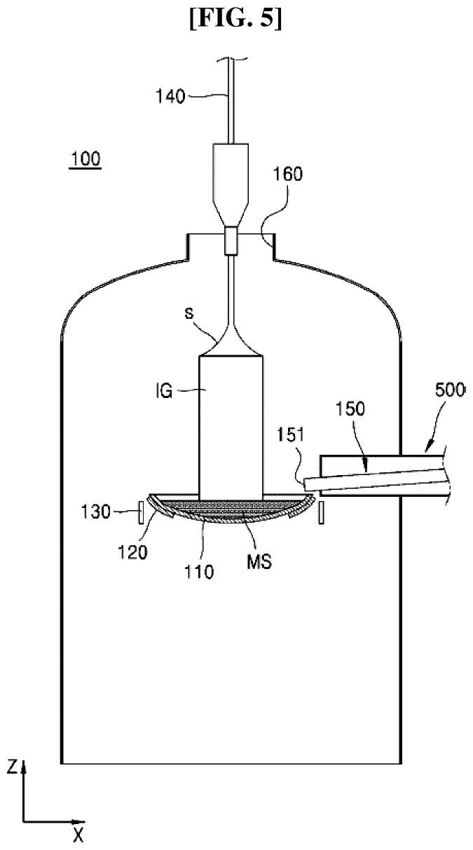

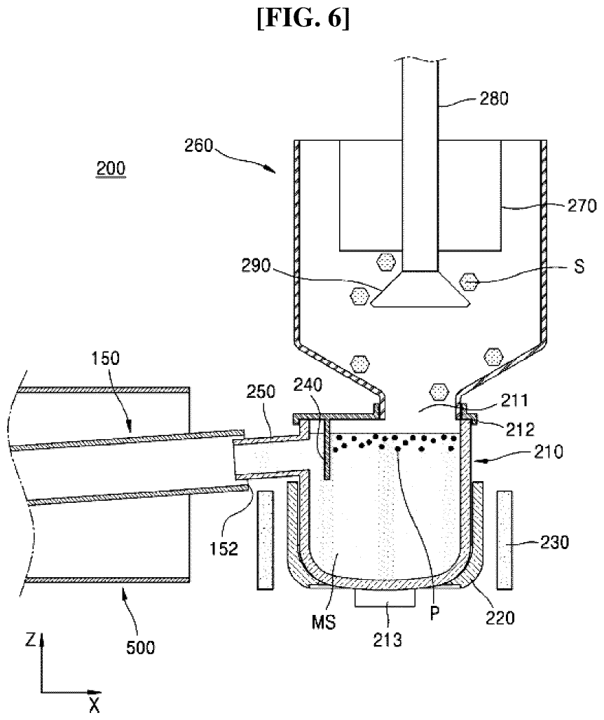

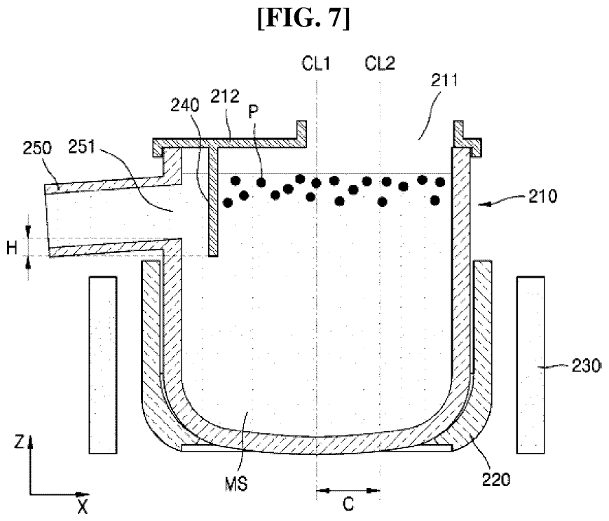

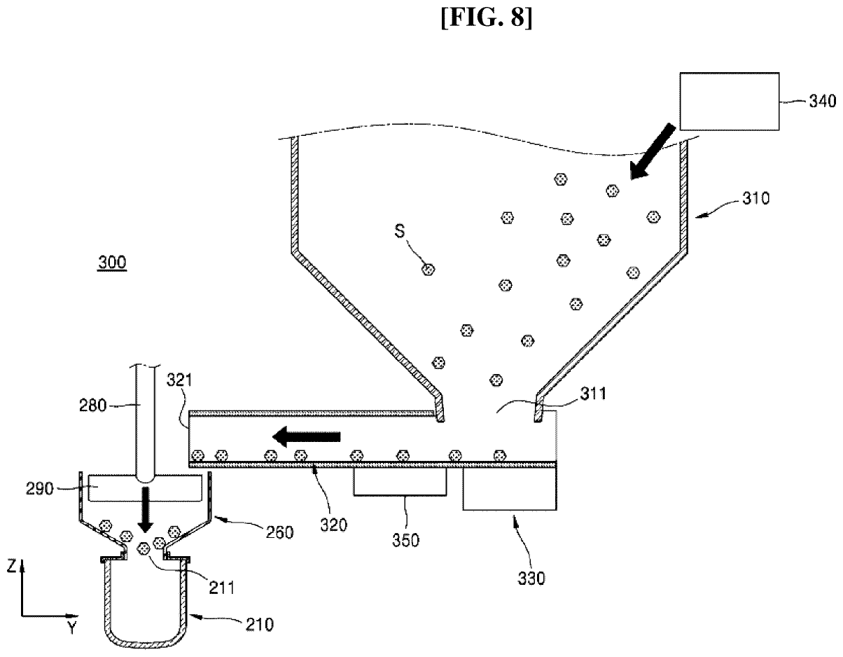

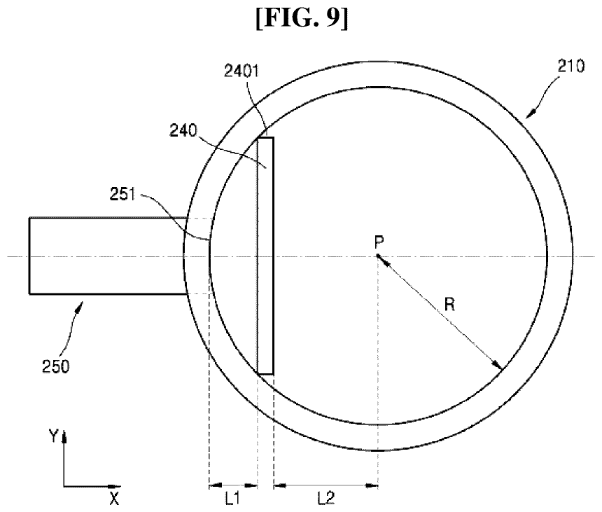

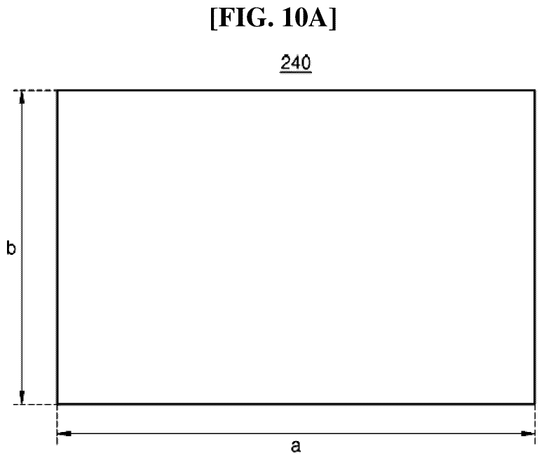

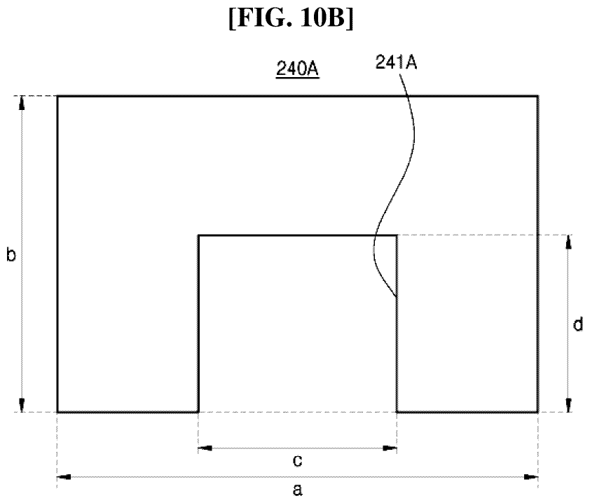

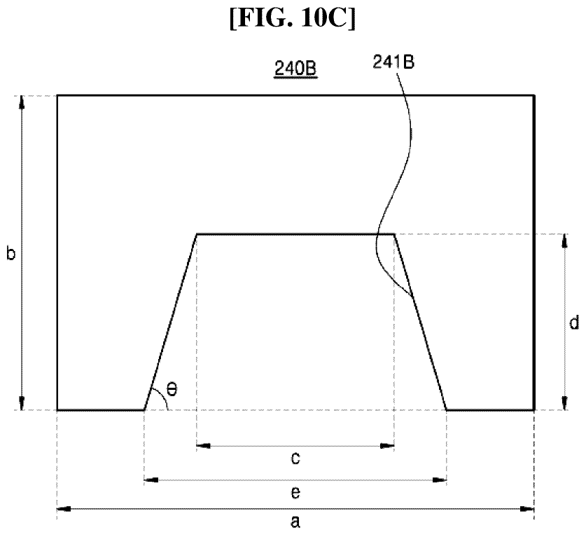

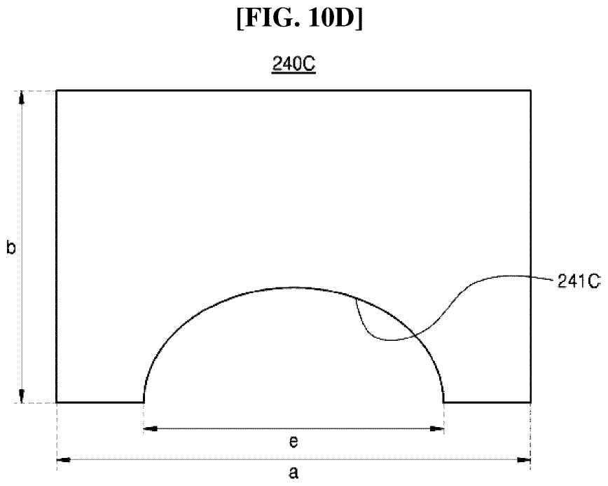

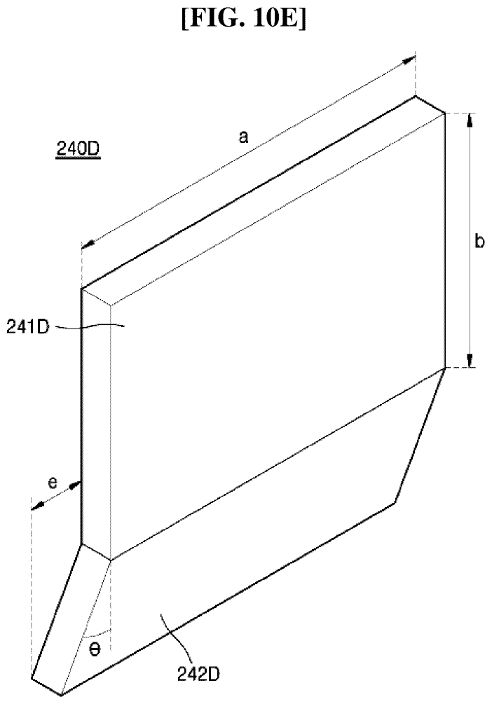

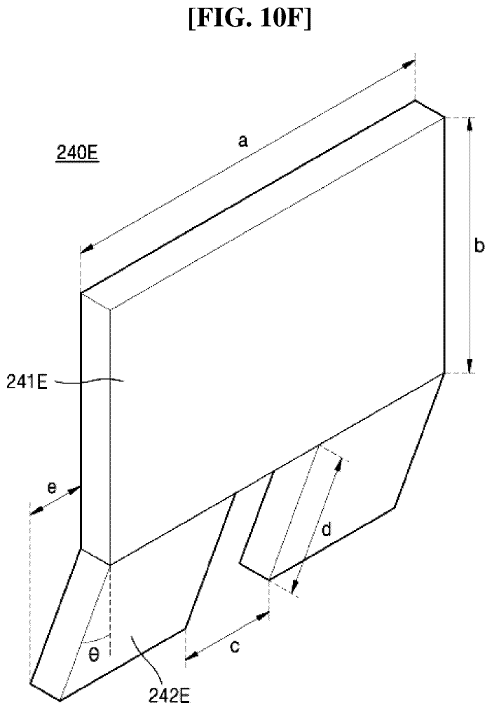

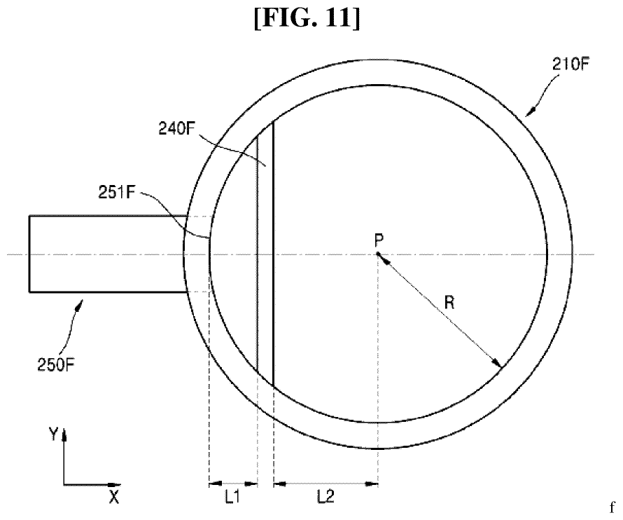

FIG. 1 shows an entire ingot growth apparatus 10, and FIGS. 2 to 4 show portions of the ingot growth apparatus 10. FIG. 5 shows an inner portion of the ingot growth furnace 100, and FIG. 6 shows an inner portion of an auxiliary melting furnace 200. FIG. 7 shows the enlarged inner portion of the auxiliary melting furnace 200 of FIG. 6, and FIG. 8 shows an inner portion of a silicon feeder 300. FIG. 9 shows the auxiliary melting furnace 200, and FIG. 10 shows partition walls 240 according to some embodiments. FIG. 11 shows an auxiliary melting furnace 200 according to another embodiment.

Referring to FIGS. 1 to 9, the ingot growth apparatus 10 is an apparatus for growing an ingot IG which is a raw material of a silicon wafer and may be an apparatus, for example, for manufacturing a silicon (Si) or gallium arsenide (GaAs) single crystal ingot. The ingot IG manufactured by the ingot growth apparatus 10 may be manufactured into a single crystal silicon wafer for a solar cell. For example, the ingot growth apparatus 10 may be a single crystal silicon ingot growth apparatus using the Czochralski method.

The ingot growth apparatus 10 may include the ingot growth furnace 100, the auxiliary melting furnace 200, the silicon feeder 300, a controller 400, a first connector 500, and a second connector 600.

The ingot growth furnace 100 may receive molten silicon from the auxiliary melting furnace 200 and grow the molten silicon into the ingot. The ingot growth furnace 100 may heat the molten silicon at a predetermined temperature and rotate the molten silicon in one direction (for example, clockwise or counter-clockwise in FIG. 5) to grow single crystal silicon. The single crystal silicon may be pulled upward from the ingot growth furnace 100 and grown vertically. In the inner portion of the ingot growth furnace 100, an atmosphere of a vacuum or an inert gas, such as helium or argon, may be maintained.

The ingot growth furnace 100 may include a main crucible 110, a first main heater 120, a first auxiliary heater 130, a pulling wire 140, and a first transfer path 150.

The main crucible 110 may be located in the ingot growth furnace 100 and may heat to melt the silicon. For example, as shown in FIG. 5, the main crucible 110 may have a shape that is concave downward and accommodate molten silicon MS therein. The main crucible 110 may receive the molten silicon MS from the auxiliary melting furnace 200 or receive solid silicon S from the silicon feeder 300 through the first transfer path 150. In addition, the main crucible 110 may be formed of a material with superior heat-resistance, such as quartz.

The first main heater 120 may be close to the main crucible 110 or connected to the main crucible 110 and may heat the main crucible 110 to maintain a liquid state of the molten silicon MS accommodated in the main crucible 110. For example, as shown in FIG. 5, one or more first main heaters 120 may be located at the lower outside of the main crucible 110. The first main heater 120 may be a resistance heater, and when a current is applied to the main heater 120, the main heater 120 may heat to heat the main crucible 110. In addition, the first main heater 120 may generate an additional magnetic field to circulate the molten silicon MS accommodated in the main crucible 110 to adjust an oxygen concentration.

The first auxiliary heater 130 may surround the main crucible 110 to be spaced apart from the main crucible 110. Like the first main heater 120, the first auxiliary heater 130 may be a resistance heater, and when a current is applied to the first auxiliary heater 130, the first auxiliary heater 130 may heat to additionally heat the main crucible 110. The first auxiliary heater 130 may selectively operate according to an amount of the molten silicon MS accommodated in the main crucible 110, a growth rate of the ingot IG, and/or the like.

The pulling wire 140 may be inserted through an opening 160 formed in an upper portion of the ingot growth furnace 100, and a seed s may be connected to a lower end of the pulling wire 140. The pulling wire 140 may be rotated and pulled at a predetermined speed by a pulling apparatus which is not illustrated. The pulling wire 140 may descend to bring the seed s into contact with the molten silicon MS of the main crucible 110 and then ascend while being rotated by the pulling apparatus. Accordingly, the ingot IG may be grown downward from the seed s.

The first transfer path 150 is a path connected to the ingot growth furnace 100 and may receive the molten silicon MS in a state in which the ingot growth furnace 100 is connected to the auxiliary melting furnace 200. The first transfer path 150 is a prismatic or tube type path inserted into a side surface of the ingot growth furnace 100, and an outlet 151 thereof may be located above the main crucible 110. The first transfer path 150 may be inclined downward toward the main crucible 110, and the molten silicon MS supplied from the auxiliary melting furnace 200 may be introduced into the main crucible 110 through the first transfer path 150 and the outlet 151.

Alternatively, in a state in which the ingot growth furnace 100 is connected to the silicon feeder 300, the first transfer path 150 may receive the solid silicon S from the silicon feeder 300. Similarly, the solid silicon S may be introduced into the main crucible 110 through the outlet 151 and melted.

In the first transfer path 150, the outlet 151 may be located in the ingot growth furnace 100, and an inlet 152 may be located outside the ingot growth furnace 100. The first transfer path 150 may be located in the first connector 500.

The auxiliary melting furnace 200 may supply the molten silicon MS to the ingot growth furnace 100. For example, as shown in FIGS. 1 to 3, the auxiliary melting furnace 200 may be connected to the ingot growth furnace 100 through the first connector 500. Alternatively, the auxiliary melting furnace 200 may be connected to the silicon feeder 300 through the second connector 600. Accordingly, the auxiliary melting furnace 200 may receive the solid silicon from the silicon feeder 300, melt the solid silicon to generate the molten silicon MS, and supply the molten silicon MS to the ingot growth furnace 100.

The auxiliary melting furnace 200 may include an auxiliary crucible 210, a second main heater 220, a second auxiliary heater 230, a partition wall 240, a second transfer path 250, a first hopper 260, a discharge port 270, a support rod 280, and a guide 290.

The auxiliary crucible 210 accommodates and melts the solid silicon S input from the silicon feeder 300 to generate the molten silicon MS. For example, as shown in FIG. 6, the auxiliary crucible 210 may have a cross section having a deep “U” shape to accommodate the solid silicon S and the molten silicon MS. An upper portion of the auxiliary crucible 210 may be closed by a cover 212, and the auxiliary crucible 210 may be connected to the first hopper 260 through an input port 211.

The input port 211 may be formed to be biased to one side from a center of the auxiliary crucible 210. For example, as shown in FIG. 7, the auxiliary crucible 210 may have a central axis CL1, and the central axis CL1 may be spaced a distance C from a central axis CL2 of the input port 211 in a radial direction.

The input port 211 may be located at a side opposite to the partition wall 240 and/or second transfer path 250 based on the central axis CL1 of the auxiliary crucible 210. For example, as shown in FIG. 7, the input port 211 may be located at one side of the central axis CL1, and the partition wall 240 and the second transfer path 250 may be located at the other side of the central axis CL1 to face the input port 211. Accordingly, the solid silicon S input from the first hopper 260 through the input port 211 may be located at a maximal distance from the partition wall 240 and the second transfer path 250. In addition, foreign matter P contained in the unmolten solid silicon S or solid silicon S may be prevented from being introduced into the second transfer path 250 over the partition wall 240.

The distance C between the central axis CL1 and the central axis CL2 may range from 30% to 70% of a radius R of the auxiliary crucible 210. When the distance C is smaller than 30% of the radius R of the auxiliary crucible 210, a portion of the solid silicon S or the foreign matter P contained therein may be introduced into the second transfer path 250. When the distance C is greater than 70% of the radius R of the auxiliary crucible 210, the input port 211 may be excessively biased to one side of the auxiliary crucible 210, and thus the input port 211 may be closed and blocked by the solid silicon S. For example, the distance C may range from 40% to 60% of the radius R of the auxiliary crucible 210.

The second main heater 220 may be close to the auxiliary crucible 210 or connected to the auxiliary crucible 210 and heat the auxiliary crucible 210 to melt the solid silicon S accommodated therein. For example, the second main heater 220 may have a shape corresponding to the auxiliary crucible 210, be located under the auxiliary crucible 210, and partially surround a lower surface and a side surface of the auxiliary crucible 210.

The second auxiliary heater 230 may be located outside the auxiliary crucible 210 to surround the auxiliary crucible 210. The second auxiliary heater 230 may be located outside the second main heater 220 and have a cylindrical shape of which upper and lower portions are open. The second main heater 220 and the second auxiliary heater 230 may be electrically heating heaters.

At least a portion of the partition wall 240 is located in the auxiliary crucible 210, and the partition wall 240 prevents the solid silicon S and the foreign matter P of the solid silicon S from being introduced into the ingot growth furnace 100 through the second transfer path 250. For example, as shown in FIG. 7, the partition wall 240 may extend downward from an upper surface of the auxiliary crucible 210. The partition wall 240 may be spaced apart from the central axis CL1 of the auxiliary crucible 210 to be close to the second transfer path 250. Accordingly, even when a portion of the solid silicon S input from the first hopper 260 and the foreign matter P sinks below a surface of the molten silicon MS, the partition wall 240 may block the second transfer path 250 to prevent the solid silicon S and the foreign matter P from being introduced into the second transfer path 250.

The partition wall 240 may extend across the auxiliary crucible 210. For example, as shown in FIG. 9, the partition wall 240 may not pass through a center P of the auxiliary crucible 210, and both ends of the partition wall 240 may be located between inner surfaces of the auxiliary crucible 210. Accordingly, the partition wall 240 may extend between two facing points of the inner surfaces of the auxiliary crucible 210 and have a shape like a chord. In this case, the partition wall 240 may be fixed to the cover 212 provided on the auxiliary crucible 210 without being fixed to the inner surface of the auxiliary crucible 210. Accordingly, as shown in FIG. 9, there may be gaps 2401 between both ends of the partition wall 240 and the inner surface of the auxiliary crucible 210, and the solid silicon S and the foreign matter P may accumulate in the gaps 2401.

In the auxiliary crucible 210, since densities of the solid silicon S and the foreign matter P are relatively low, the solid silicon S and the foreign matter P mainly float on the surface, and in particular, are mainly located at an edge along the inner surface of the auxiliary crucible 210. Accordingly, the solid silicon S and the foreign matter P may be intensively located in the gaps 2401 between the partition wall 240 and the auxiliary crucible 210 so that other solid silicon S and foreign matter P may be collected in the gaps 2401.

The partition wall 240 may extend further downward than a lower end of the inlet 251 of the second transfer path 250 by a height H. Accordingly, the solid silicon S and the foreign matter P close to the partition wall 240 may be more reliably prevented from being introduced into the second transfer path 250.

In the partition wall 240, a surface facing the second transfer path 250 (for example, an outer surface) may be spaced a distance L1 from the inlet 251 of the second transfer path 250. In addition, in the partition wall 240, a surface facing the center of the auxiliary crucible 210 (for example, an inner surface) may be spaced a distance L2 from the center of the auxiliary crucible 210. In addition, the distance L1 may be smaller than the distance L2. That is, as the partition wall 240 is located closer to the second transfer path 250 than to the center of the auxiliary crucible 210, a space through which the solid silicon and the foreign matter P are introduced into the second transfer path 250 may be reduced.

The distance L1 may range from 20% to 70% of the distance L2. When the distance L1 is smaller than 20% of the distance L2, the partition wall 240 may be extremely close to the second transfer path 250, and thus a flow of the molten silicon MS introduced into the second transfer path 250 may be hindered. When the distance L1 is greater than 70% of the distance L2, the partition wall 240 may be extremely far away from the second transfer path 250, and thus a possibility of the solid silicon and the foreign matter P being introduced into the second transfer path 250 may increase. In addition, the partition wall 240 may be long, and thus the partition wall 240 may hinder a flow of the molten silicon MS. As one example, the distance L1 may range from 30% to 60% of the distance L2.

As shown in FIG. 10, the partition wall 240 may have any of various shapes.

For example, as shown in FIG. 10A, a partition wall 240 may have a rectangular cross section with a width a and a length b. The width a of the partition wall 240 may range from 1.1 to 1.5 times a radius R of the auxiliary crucible 210. When the width a is less than 1.1 times the radius R, the partition wall 240 may be extremely close to the second transfer path 250 and thus hinder a flow of the molten silicon MS moving to the second transfer path 250. When the width a is greater than 1.5 times the radius R, an area of the partition wall 240 is extremely wide, and thus the partition wall 240 may similarly hinder a flow of the molten silicon MS. In addition, a region through which the solid silicon S is input is extremely small, and thus there is a possibility of the solid silicon S closing and blocking the input port 211. As one example, the width a may range from 1.2 to 1.4 times the radius R of the auxiliary crucible 210.

As described above, the length b of the partition wall 240 may have a value corresponding to a lower end of the partition wall 240 being spaced apart from a lower end of the inlet 251 by a height H.

Alternatively, as shown in FIG. 10B, a partition wall 240A may have a rectangular cross section with a width a and a length b and include a groove 241A thereinside. In addition, the groove 241A may have a rectangular shape with a width c and a length d. That is, since the partition wall 240A includes the groove 241A formed by cutting a portion of a lower end portion of the partition wall 240A, a normal flow of the molten silicon MS may be sufficiently secured through the groove 241A, and the remaining portion may block a flow of the solid silicon S and the foreign matter P. Accordingly, in the partition wall 240A, a size in which a length between both end portions in a longitudinal direction (for example, a left-right direction of FIG. 10B) is greater than that in a height direction (for example, a vertical direction of FIG. 10B) may be secured in order to block the solid silicon S and the foreign matter P without hindering a flow of the molten silicon MS. In addition, the partition wall 240A may prevent the solid silicon S and the foreign matter P mainly positioned at an edge of the auxiliary crucible 210 from being introduced into the second transfer path 250 while hindering a flow of the molten silicon MS less.

Alternatively, as shown in FIG. 10C, a partition wall 240B may have a rectangular cross section with a width a and a length b and include a groove 241B thereinside. In addition, the groove 241B may have a trapezoidal shape with a short side c, a height d, and a long side e. That is, since the partition wall 240B includes the groove 241B formed by cutting a portion of a lower end portion of the partition wall 240B, a normal flow of the molten silicon MS may be sufficiently secured through the groove 241B, and the remaining portion may block a flow of the solid silicon S and the foreign matter P. In particular, when the groove 241B has a downwardly inclined shape, a region through which the molten silicon MS flows may be more widely secured. Accordingly, in the partition wall 240B, a length between both ends in a longitudinal direction greater than that in a height direction may be secured in order to block the solid silicon S and the foreign matter P without hindering a flow of the molten silicon MS. In addition, the solid silicon and the foreign matter P mainly positioned at the edge of the auxiliary crucible 210 may be prevented from being introduced into the second transfer path 250 while hindering a flow of the molten silicon MS less.

A slope θ of the groove 241B may range from 45° to 75°. When the slope θ is smaller than 45°, the lower end of the partition wall 240B excluding the groove 241B may be extremely small, and thus the solid silicon or the foreign matter P may pass through the groove 241B. When the slope θ is greater than 75°, a size of the groove 241B may be small, and thus an effect allowing the molten silicon MS to easily flow may be reduced. For example, the slope θ may range from 50°to 70°.

Alternatively, as shown in FIG. 10D, a partition wall 240C may have a rectangular cross section with a width a and a length b and include a groove 241C formed by cutting a portion of a lower end portion or the partition wall 240C. In addition, the groove 241B may have an elliptical shape with a height d and a width e.

Alternatively, as shown in FIG. 10E, a partition wall 240D may include a main body portion 241D and an inclined portion 242D. The main body portion 241D may have a rectangular cross section with a width a and a length b, and the inclined portion 242D may extend to be inclined toward one side from a lower end of the main body portion 241D. For example, the inclined portion 242D may have a rectangular cross section like the main body portion 241D and be inclined at a slope θ toward the outside (toward the second transfer path 250) from the lower end of the main body portion 241D. In addition, an outer end portion of the inclined portion 242D may be spaced a distance e from an outer surface of the main body portion 241D. Accordingly, the partition wall 240D may prevent the solid silicon or the foreign matter P, which has temporarily sunk under the molten silicon MS, from being introduced into the second transfer path 250.

Alternatively, as shown in FIG. 10F, a partition wall 240E may include a main body portion 241E, an inclined portion 242E, and a groove 243E. The main body portion 241E has a rectangular cross section with a width a and a length b, and the inclined portion 242E extends to be inclined toward one side from a lower end of the main body portion 241E. The inclined portion 242E may be inclined at a slope θ from the lower end of the main body portion 241D toward the outside (toward the second transfer path 250), and an outer end portion of the inclined portion 242D may be spaced a distance e from an outer surface of the main body portion 241D.

In addition, the groove 243E may be formed by cutting a portion of a lower end portion of the inclined portion 242E. As shown in FIG. 10E, the groove 243E may have a rectangular cross section with a width c and a length d, and the inclined portion 242E may be formed at both sides thereof. The molten silicon MS may flow smoothly through the groove 243E, and the inclined portion 242E may prevent the solid silicon and the foreign matter P from being introduced into the second transfer path 250.

As another embodiment, as shown in FIG. 11, in a partition wall 240F, both ends in a longitudinal direction may be fixed to an inner surface of an auxiliary crucible 210f. Accordingly, unlike the partition wall 240 according to the above-described embodiment, gaps 2401 may not be formed between the partition wall 240F and an inner surface of the auxiliary crucible 210f. Accordingly, even when molten silicon MS flows, the partition wall 240F may be stably supported by the auxiliary crucible 210f.

The second transfer path 250 may be connected to the auxiliary crucible 210, and the molten silicon MS may be transferred to the first transfer path 150 through the second transfer path 250. For example, as shown in FIG. 6, the second transfer path 250 may be connected to the side surface of the auxiliary crucible 210 close to the partition wall 240 and extend to be inclined downward. In the state in which the auxiliary melting furnace 200 is connected to the ingot growth furnace 100, the second transfer path 250 may be connected to the first transfer path 150. For example, as shown in FIG. 6, a portion of the second transfer path 250 may be inserted into the inlet 152 of the first transfer path 150.

A lower end of the second transfer path 250 may be located at a higher level than a lower end of the partition wall 240 by the height H.

The second transfer path 250 may be located at a side opposite to the input port 211 based on the central axis CL1 of the auxiliary crucible 210.

The first hopper 260 is located above the auxiliary crucible 210 and supplies the solid silicon supplied from the silicon feeder 300 to the auxiliary crucible 210. For example, as shown in FIG. 6, the first hopper 260 may include the discharge port 270 connected to the silicon feeder 300. In addition, the first hopper 260 may be connected to the auxiliary crucible 210 through the input port 211 and coaxially located with the central axis CL2 of the input port 211. The solid silicon discharged through the discharge port 270 may be input to the auxiliary crucible 210 through the first hopper 260 and the input port 211 and melted.

The first hopper 260 may have a cylindrical shape, and a lower portion thereof may have an inwardly inclined conical shape. The solid silicon discharged through the discharge port 270 may be input to the input port 211 along an inclined surface of the lower portion.

The support rod 280 may be inserted into the first hopper 260, and an upper end thereof may be connected to an upper end of the auxiliary melting furnace 200 which is not illustrated. In addition, the guide 290 may be located on a lower end of the support rod 280.

The guide 290 may disperse the solid silicon S to prevent the solid silicon discharged through the discharge port 270 from being biased to and accumulated at one side in the first hopper 260. For example, as shown in FIG. 6, the guide 290 may have a trapezoidal shape in which a cross-sectional area increases downward and which has an inclined surface at both sides. The solid silicon S discharged through the discharge port 270 may be dispersed toward both sides based on a central axis of the first hopper 260 along the inclined surface of the guide 290 and then fall.

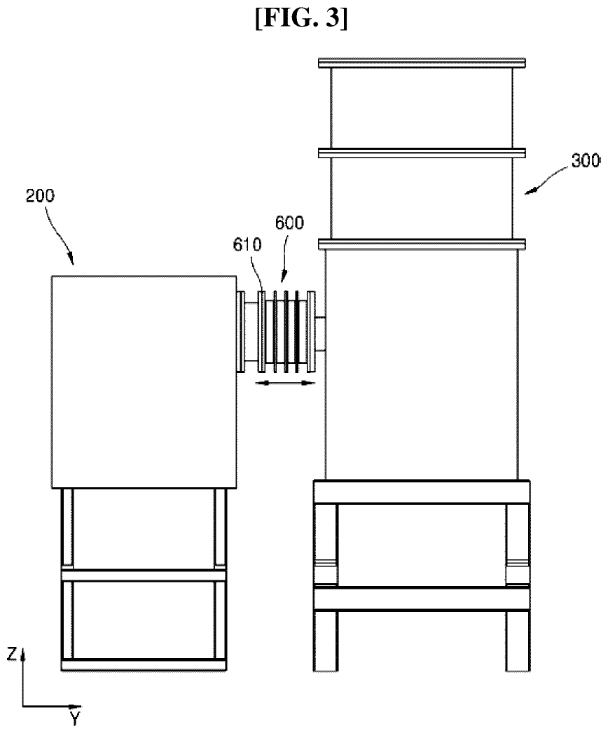

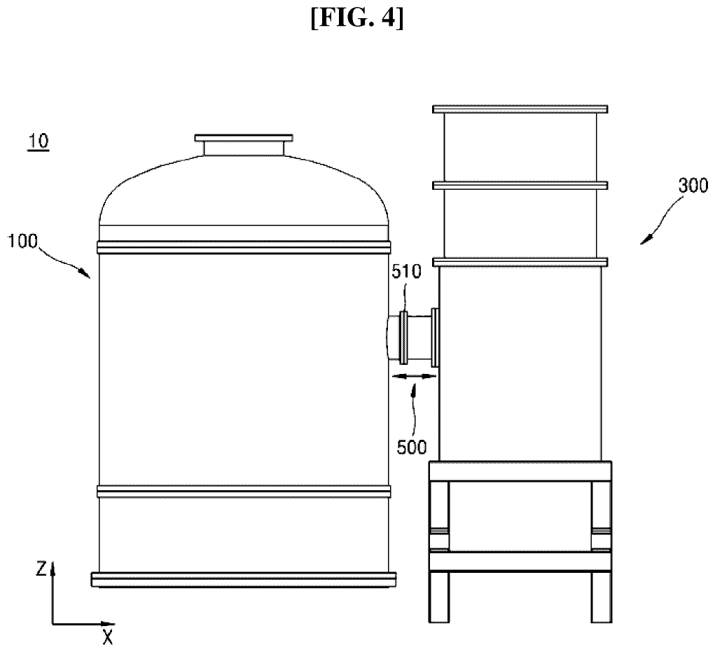

The silicon feeder 300 supplies the solid silicon S to the ingot growth furnace 100 or the auxiliary melting furnace 200. For example, as shown in FIG. 3, the silicon feeder 300 may be connected to the auxiliary melting furnace 200 and supply the solid silicon S to the auxiliary melting furnace 200, and the auxiliary melting furnace 200 may melt the solid silicon S and supply the molten silicon MS to the ingot growth furnace 100. Alternatively, as shown in FIG. 4, the silicon feeder 300 may be directly connected to the ingot growth furnace 100 and supply the solid silicon S to the ingot growth furnace 100.

The silicon feeder 300 may include a second hopper 310, a solid silicon input path 320, and a transfer member 330.

The solid silicon S input to the second hopper 310 may move to the solid silicon input path 320 through a connecting port 311. The solid silicon input path 320 is a prismatic or tube type path extending in one direction (for example, a Y-axis direction of FIG. 8), and an outlet 321 thereof may face the first hopper 260. In addition, the transfer member 330 may surround the solid silicon input path 320 or be connected to a lower end of the solid silicon input path 320 and transfer the solid silicon S. For example, the transfer member 330 is a vibrator and may vibrate the solid silicon input path 320 at a lower surface of the solid silicon input path 320 to move the solid silicon in the solid silicon input path 320.

The outlet 321 of the solid silicon input path 320 may be located above the guide 290. In addition, the outlet 321 of the solid silicon input path 320 may correspond to the discharge port 270. Accordingly, the solid silicon discharged through the solid silicon input path 320 may fall on the guide 290 and then be input to the first hopper 260.

In the ingot growth apparatus 10, the components may be modularized, assembled as different combinations, and dissembled. For example, the ingot growth furnace 100, the auxiliary melting furnace 200, and the silicon feeder 300 may be freely assembled with each other and dissembled. For example, the ingot growth furnace 100 and the auxiliary melting furnace 200 may be assembled with each other, the auxiliary melting furnace 200 and the silicon feeder 300 may be assembled with each other, or the ingot growth furnace 100 and the silicon feeder 300 may be assembled with each other. In addition, the ingot growth furnace 100 and the auxiliary melting furnace 200, the auxiliary melting furnace 200 and the silicon feeder 300, or the ingot growth furnace 100 and the silicon feeder 300 may be dissembled from the assembled state. In addition, the ingot growth furnace 100, the auxiliary melting furnace 200, and the silicon feeder 300 may all be assembled with each other.

The ingot growth apparatus 10 may be modularized such that the components are allowed to be assembled with each other and dissembled. That is, as the ingot growth furnace 100, the auxiliary melting furnace 200, and the silicon feeder 300 are modularized, the ingot growth furnace 100, the auxiliary melting furnace 200, and the silicon feeder 300 may all be assembled as needed, and the solid silicon S may be melted using the auxiliary melting furnace 200 and then supplied to the ingot growth furnace 100. Alternatively, the solid silicon S may be directly supplied from the silicon feeder 300 to the ingot growth furnace 100 without passing through the auxiliary melting furnace 200. In addition, the ingot growth furnace 100, the auxiliary melting furnace 200, and the silicon feeder 300 may be separated, and maintenance and repair operations may be easily performed thereon.

The silicon feeder 300 may further include a silicon inputter 340 and a third load cell 350. The silicon inputter 340 may input the solid silicon S to the second hopper 310 from around the second hopper 310. The silicon inputter 340 may receive an instruction from a predetermined program or the controller 400 to input the solid silicon S to the second hopper 310. For example, the controller 400 may adjust an amount of the solid silicon S input from the silicon inputter 340 to adjust a melt gap. In the drawings, it is illustrated that the silicon inputter 340 is located beside the second hopper 310, but the present invention is not limited thereto. The silicon inputter 340 may be located above the second hopper 310.

The controller 400 may be connected to the ingot growth furnace 100, the auxiliary melting furnace 200, and the silicon feeder 300 with and/or without a wire and control the ingot growth furnace 100, the auxiliary melting furnace 200, and the silicon feeder 300. For example, as shown in FIG. 1, the controller 400 may be located on a support frame and close to the auxiliary melting furnace 200 and/or the silicon feeder 300. For example, the controller 400 may control a towing and pulling speed of the pulling wire 140 of the ingot growth furnace 100, a temperature of the first main heater 120, and a temperature of the first auxiliary heater 130. In addition, the controller 400 may control a temperature of the second main heater 220 and a temperature of the second auxiliary heater 230 of the auxiliary melting furnace 200. In addition, the controller 400 may control an input amount of the solid silicon of the silicon feeder 300.

The first connector 500 and the second connector 600 may connect the ingot growth furnace 100, the auxiliary melting furnace 200, and the silicon feeder 300. For example, the first connector 500 may be connected to one side of the ingot growth furnace 100 and connected to the auxiliary melting furnace 200 or the silicon feeder 300. For example, as shown in FIG. 2, the first connector 500 may be connected to each of the side surface of the ingot growth furnace 100 and a side surface of the auxiliary melting furnace 200. The first connector 500 may be installed such that the first transfer path 150 of the ingot growth furnace 100 and the second transfer path 250 of the auxiliary melting furnace 200 are located inside the first connector 500.

Alternatively, as shown in FIG. 4, the first connector 500 may be connected to each of the side surface of the ingot growth furnace 100 and a side surface of the silicon feeder 300. The first connector 500 may be installed such that the first transfer path 150 of the ingot growth furnace 100 and the solid silicon input path 320 of the silicon feeder 300 are located inside the first connector 500. The installation location of the first connector 500 may be set by adjusting a height of a support or frame supporting the auxiliary melting furnace 200 and the silicon feeder 300. The first connector 500 may include a connecting member 510, and the connecting member 510 may be a connecting unit in an airlock type.

One side of the first connector 500 may be fixed to the ingot growth furnace 100. Accordingly, in the state in which the ingot growth furnace 100 is connected to the auxiliary melting furnace 200, the ingot growth furnace 100 may be disconnected from the auxiliary melting furnace 200 and then connected to another auxiliary melting furnace 200 or silicon feeder 300. Alternatively, in the state in which the ingot growth furnace 100 is connected to the silicon feeder 300, the ingot growth furnace 100 may be disconnected from the silicon feeder 300 and then connected to another silicon feeder 300 or auxiliary melting furnace 200.

Alternatively, as shown in FIG. 3, the second connector 600 may be connected to each of the side surface of the auxiliary melting furnace 200 and the side surface of the silicon feeder 300. The second connector 600 may be installed such that the solid silicon input path 320 of the silicon feeder 300 is located inside the second connector 600. The installation location of the second connector 600 may be set by adjusting the height of the support or frame supporting the auxiliary melting furnace 200 and the silicon feeder 300. The second connector 600 may include a connecting member 610, and the connecting member 610 may be a connecting unit in an airlock type.

One side of the second connector 600 may be connected to the auxiliary melting furnace 200. Accordingly, in a state in which the auxiliary melting furnace 200 is connected to the silicon feeder 300, the auxiliary melting furnace 200 may be disconnected from the silicon feeder 300 and then connected to another silicon feeder 300. Alternatively, conversely, the second connector 600 may be fixed to the silicon feeder 300. Accordingly, in the state in which the silicon feeder 300 is connected to the auxiliary melting furnace 200, the silicon feeder 300 may be disconnected from the auxiliary melting furnace 200 and then connected to another auxiliary melting furnace 200.

### INDUSTRIAL APPLICABILITY

Some embodiments of the present disclosure can be used in industries relating to ingot growth apparatuses.

1. An ingot growth apparatus comprising:
an ingot growth furnace which heats molten silicon; and
an auxiliary melting furnace which melts solid silicon and supplies the molten silicon to the ingot growth furnace,
wherein the auxiliary melting furnace includes:
an auxiliary crucible which melts the solid silicon;
a first transfer path connected to the auxiliary crucible and connected to the ingot growth furnace; and
a partition wall which extends downward from an upper surface of the auxiliary crucible, is located between a center of the auxiliary crucible and an inlet of the first transfer path, and extends between two facing points of an inner surface of the auxiliary crucible.

2. The ingot growth apparatus of claim 1, wherein:
a lower end of the partition wall is located at a higher level than a lower end of the inlet of the first transfer path; and
a distance between the partition wall and the inlet of the first transfer path is smaller than a distance between the partition wall and a center of the auxiliary crucible.

3. The ingot growth apparatus of claim 1, wherein:
the partition wall includes a groove formed by cutting a portion of a lower end portion of the partition wall; and
a height of a portion of the partition wall close to the inner surface of the auxiliary crucible is greater than a height of a central portion of the partition wall.

4. The ingot growth apparatus of claim 1, wherein gaps are formed between both ends of the partition wall in a longitudinal direction and the inner surface of the auxiliary crucible.

5. The ingot growth apparatus of claim 1, wherein the partition wall includes:
a main body portion extending downward from the upper surface of the auxiliary crucible; and
an inclined portion which extends to be inclined from the main body portion toward the first transfer path and is spaced apart from the inlet of the first transfer path.

6. The ingot growth apparatus of claim 1, wherein:
the auxiliary melting furnace includes a first hopper which transfers the solid silicon from a silicon feeder to the auxiliary crucible and is connected to the auxiliary crucible through an input port; and
a central axis of the first hopper is located at a side opposite to the partition wall based on a central axis of the auxiliary crucible.

7. The ingot growth apparatus of claim 6, wherein the first hopper includes:
a support rod located on the central axis of the first hopper;
a raw material input path through which the first hopper and the silicon feeder are connected; and
a guide including a pair of inclined surfaces which are located on a lower end of the support rod to be located under the raw material input path and are inclined downward toward an inner surface of the first hopper.

8. The ingot growth apparatus of claim 6, wherein:
a distance between the central axis of the first hopper and the central axis of the auxiliary crucible ranges from 30% to 70% of a radius of the auxiliary crucible;
a distance between the partition wall and the inlet of the first transfer path ranges from 20% to 70% of a distance between the partition wall and the center of the auxiliary crucible; and
a length of the partition wall ranges from 1.1 to 1.5 times the radius of the auxiliary crucible.

9. The ingot growth apparatus of claim 1, wherein the ingot growth furnace and the auxiliary melting furnace are couplable and separable.
